(19) United States
(12) Patent Application Publication
(10) Pub. No.: US 2019/0020305 A1
(43) Pub. Date: Jan. 17, 2019

(54) SOLAR CELL MODULE PACKAGING STRUCTURE AND SOLAR POWER GENERATION DEVICE

(71) Applicant: Panasonic Intellectual Property Management Co., Ltd., Osaka (JP)

(72) Inventors: Yukihiro Yoshimine, Osaka (JP); Takahiro Haga, Osaka (JP)

(73) Assignee: Panasonic Intellectual Property Management Co., Ltd., Osaka (JP)

(21) Appl. No.: 16/134,199

(22) Filed: Sep. 18, 2018

Related U.S. Application Data
(63) Continuation of application No. PCT/JP2017/000221, filed on Jan. 6, 2017.

(30) Foreign Application Priority Data
Mar. 22, 2016 (JP) 2016-056764

(51) Int. Cl. H02S 30/10; H02S 20/23; H02S 40/34; H01L 31/043

(52) U.S. Cl. CPC H02S 30/10; H01L 31/043; H02S 40/34; H02S 20/23

(57) ABSTRACT

A solar cell module packaging structure enables two solar cell modules to be stacked and packaged, the solar cell module including a solar cell panel and a frame having a groove into which an end edge of the solar cell panel is inserted and fixed, wherein the frame is fixed only to one end edge of two end edges in a predetermined direction in the solar cell panel, one of the two solar cell modules is disposed upside down and the other thereof is stacked thereon, in this state, rear surfaces of the solar cell panels included in the respective two solar cell modules face each other, the rear surface being a surface on an opposite side to a surface, of the solar cell panel, which solar light is directly incident on, and a space is formed between the rear surfaces.

### INCORPORATION BY REFERENCE

The present application is a continuation under 35 U.S.C. § 120 of PCT/JP2017/000221, filed Jan. 6, 2017, which is incorporated herein by reference and which claimed priority to Japanese Patent Application No. 2016-056764 filed Mar. 22, 2016. The present application likewise claims priority under 35 U.S.C. § 119 to Japanese Patent Application No. 2016-056764 filed Mar. 22, 2016, the entire content of which is also incorporated herein by reference.

### TECHNICAL FIELD

The present disclosure relates to a solar cell module packaging structure and a solar power generation device.

### BACKGROUND

There is conventionally known a solar cell module in which a frame made of a metal, for example, composed of aluminum alloy is fixed in advance to four side end edges of a solar cell in a rectangular shape such as, for example, a rectangular shape with an adhesive agent or the like.

### CITATION LIST

### Patent Literature

### Patent Literature 1: JP 2006-100439 A

### SUMMARY

### Technical Problem

There is occasionally provided a terminal box for collecting and outputting electric power generated by a solar cell panel, on the rear surface on an opposite side to a light receiving surface in the solar cell panel constituting a solar cell module, in the state where the terminal box protrudes from the rear surface of the solar cell panel. When such solar cell modules are packaged, the packaging needs to be designed so as not to exert external force on the terminal box. Such a problem can arise not only in the case of a solar cell panel in a so-called frameless structure but also in the case where an attachment composed of a metal, an elastic body or the like which is thinner than the protruding height of the terminal box is attached to the end edge of a solar cell panel.

It is an advantage of the present disclosure to provide a solar cell module packaging structure which, in the case of packaging a plurality of solar cell modules, may securely package the solar cell modules such that external force is not exerted on terminal boxes on the rear surfaces of solar cell panels. Moreover, it is a further advantage of the present disclosure to provide a solar power generation device configured by installing a plurality of solar cell modules in which a frame is fixed only to one end edge of a solar cell panel in a predetermined direction on a roof.

### Solution to Problem

There is provided a solar cell module packaging structure according to an aspect of the present disclosure, the solar cell module packaging structure enabling two solar cell modules to be stacked and packaged, the solar cell module including a solar cell panel and a frame having a groove into which an end edge of the solar cell panel is inserted and fixed, wherein the frame is fixed only to one end edge of two end edges in a predetermined direction in the solar cell panel, one of the two solar cell modules is disposed upside down and the other thereof is stacked thereon, and in this state, a space is formed between rear surfaces of the solar cell panels included in the respective two solar cell modules.

Moreover, there is provided a solar power generation device according to another aspect of the present disclosure, the solar power generation device configured by installing a plurality of solar cell modules to line up in an eaves-ridge direction on a roof, the solar cell module including a solar cell panel and a frame fixed only to one end edge of two end edges in a predetermined direction in the solar cell panel, wherein the frame has a groove into which the one end edge of the solar cell panel is fixed, and other groove which opens on an opposite side to the groove, the solar power generation device includes a first solar cell module installed on a ridge side of the roof and a second solar cell module installed to line up on an eaves side with respect to the first solar cell module, and the first and second solar cell modules are installed to cause their frames to face the eaves side, and the other end edge of the solar cell panel in the predetermined direction in the second solar cell module is inserted into the other groove in the frame of the first solar cell module.

### Advantageous Effects of Invention

According to the solar cell module packaging structure which is an aspect of the present disclosure, in the case of packaging a plurality of solar cell modules, they may be securely packaged such that external force is not exerted on terminal boxes on the rear surfaces of solar cell panels.

Moreover, according to the solar power generation device which is another aspect of the present disclosure, the solar power generation device may be configured by installing a plurality of solar cell modules in which a frame is fixed only to one end edge of a solar cell panel on a roof.

### BRIEF DESCRIPTION OF DRAWINGS

FIG. 1 is a view showing a solar power generation device which is an exemplary embodiment.

FIG. 2 is a perspective view of a solar cell module constituting the solar power generation device.

FIG. 3 is a side view of the solar cell module shown in FIG. 2.

FIG. 4 is a side view exemplarily showing a solar cell module packaging structure.

FIG. 5 is a side view still exemplarily showing the solar cell module packaging structure.

FIGS. 6A and 6B are side views exemplarily showing a packaging structure in which sets of two solar cell modules are stacked into a plurality of stages.

FIG. 7 is a side view exemplarily showing a packaging structure in which sets of two solar cell modules are stacked into a plurality of stages.

FIG. 8 is a top view showing an example of providing packaging materials on both end parts of solar cell modules in a solar cell module packaging structure.

FIG. 9 is a view exemplarily showing a state where solar cell modules are installed on a roof.

FIG. 10 is a view exemplarily showing a state where a panel end part of a solar cell module is attached to a frame via a packing member.

FIG. 11 is a view still exemplarily showing a state where the panel end part of the solar cell module is attached to the frame via a packing member.

FIG. 12 is a side view exemplarily showing installation in which solar cell panels of two solar cell modules are flush with each other.

FIG. 13 is a view exemplarily showing a frame upper part detachably fastened to a frame lower part.

FIGS. 14A and 14B are views exemplarily showing an outer groove provided in the frame being formed by a detachable upper wall part.

FIG. 15 is a view showing a modification of a pressing metal fitting with which the frame of a solar cell module is fixed.

### DESCRIPTION OF EMBODIMENTS

Hereafter, embodiments according to the present disclosure are described in detail with reference to the appended drawings. In the description, specific shapes, materials, numerical values, directions and the like are exemplified for ease of understanding of the present disclosure, and can be appropriately modified so as to meet uses, purposes, specifications and the like. Moreover, when the following description hereafter includes embodiments and modifications, it is originally assumed to appropriately combine and use their characteristic portions.

Hereafter, a direction along a roof beam direction (direction perpendicular to an eaves-ridge direction of a roof) is called a “transverse direction”, and a direction perpendicular to a sheathing roof board of the roof is called an “upper/lower direction”. In the drawings, the eaves-ridge direction of the roof is indicated by an arrow α, the beam direction and the transverse direction are indicated by an arrow β, and the upper/lower direction is indicated by an arrow γ.

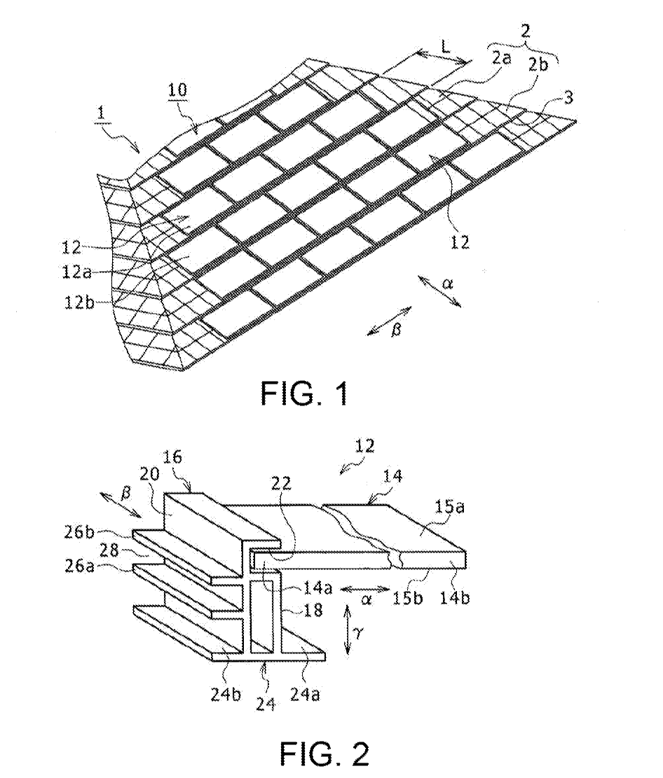

FIG. 1 is a view showing a solar power generation device 10 which is an exemplary embodiment. As shown in FIG. 1, the solar power generation device 10 is installed on a roof 1. On the roof 1, roof materials 2, for example, composed of slate tiles or the like are laid into a step-roofed shape. Namely, focusing on two roof materials 2a and 2b aligned in the eaves-ridge direction α, a ridge-side roof material 2a is overlappingly laid on the end part of an eaves-side roof material 2b in the eaves-ridge direction. Hence, there is formed a step 3 corresponding to the thickness of the roof material 2 along the beam direction β on the surface of the roof 1.

The solar power generation device 10 is attached onto the roof 1 such that a plurality of rows of solar cell modules 12 are formed along the beam direction β. The solar cell module 12 exhibits, for example, a substantially rectangular shape in plan view.

In the present embodiment, for each of the solar cell modules 12, its short sides are substantially parallel to the eaves-ridge direction α, and their arrangement is set in the state where the short sides of the solar cell modules 12 that constitute each row are in substantial contact with one another. As to the numbers of solar cell modules 12 constituting the rows extending in the beam direction β, there are a large number in the row positioned on the eaves side of the roof 1, and moreover, the number of the solar cell modules 12 may be same in a part of the rows that are adjacent to one another in the eaves-ridge direction. It should be noted that the number, the arrangement and the like of the solar cell modules 12 constituting the solar power generation device 10 are not specially limited.

The solar power generation device 10 has a structure in which the solar cell modules 12 are arranged into a step-roofed shape to conform to the step-roofed shape of the roof 1. Namely, a step is formed, caused by the eaves-side end part of a solar cell module 12a overlapping with the ridge-side end part of a solar cell module 12b between the two solar cell modules 12a and 12b adjacent to each other in the eaves-ridge direction α. Herein, out of two arbitrary solar cell modules 12 adjacent to each other in the eaves-ridge direction α, one disposed on the ridge side is the solar cell module 12a (first solar cell module), and the other disposed on the eaves side is the solar cell module 12b (second solar cell module).

The solar cell modules 12 included in the solar power generation device 10 have eaves-ridge directional lengths L the same or substantially the same as working lengths L of the roof materials 2. Thereby, by installation in which the step between the solar cell modules 12a and 12b matches the step 3 of the roof materials 2 in the step-roofed shape, the solar power generation device 10 exhibits an appearance of being integrated with the roof 1 without a feeling of incongruity, which results in an improved design.

Notably, there is described above the case where the solar power generation device 10 is installed on the roof 1 in the step-roofed shape, the structure of the solar power generation device is not limited to this. The solar power generation device 10 may be installed on a roof having a substantially flat surface shape by laying slate materials or metal plates which are thinner compared with roof tiles, or may be directly installed on a waterproof sheet laid on a roof board.

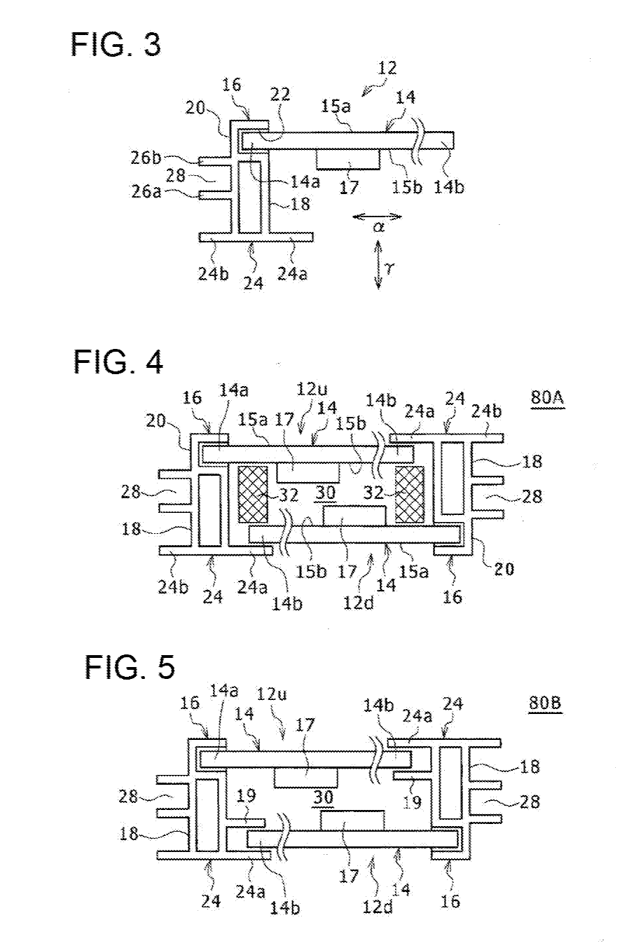

FIG. 2 is a perspective view of the solar cell module 12 constituting the solar power generation device 10. FIG. 3 is a side view of the solar cell module 12 shown in FIG. 2. FIG. 2 and FIG. 3 indicate that the upper/lower direction γ perpendicular to the sheathing roof board of the roof coincides with the height direction of the frame.

As shown in FIG. 2 and FIG. 3, the solar cell module 12 includes a solar cell panel 14 and a frame 16. The solar cell panel 14 is a panel in which a plurality of solar cell elements are sandwiched by protecting members such as glass. The solar cell panel 14 is formed into a rectangular shape such as, for example, a rectangular shape in plan view.

The solar cell panel 14 has a front surface 15a which is a light receiving surface when installed on the roof 1 as the solar cell module 12, and a rear surface 15b which is its opposite surface. As shown in FIG. 3, a terminal box 17 is attached onto the rear surface 15b of the solar cell panel 14. The terminal box 17 has a function of collecting and outputting electric power generated by the solar cell panel 14. The terminal box 17 is configured to include a casing, for example, made of resin, and is provided to protrude from the rear surface 15b of the solar cell panel 14, for example, into a rectangular solid shape.

The frame 16 of the solar cell module 12 is a longitudinal member made of a metal, for example, composed of aluminum alloy, and is fixed along an end edge 14b on one side of the solar cell panel 14. The frame 16 is fixed only to one end edge 14a out of the two end edges 14a and 14b in the eaves-ridge direction (predetermined direction) α in the solar cell panel 14. Namely, in the present embodiment, the solar cell panel 14 forms a rectangular shape in plan view, and the solar cell module 12 is installed on the roof 1 such that the long side portions of the solar cell panel 14 are along the beam direction β. Accordingly, in the solar cell module 12 the frame 16 is fixed only to the end edge 14a which is a long side portion on one side out of the two end edges 14a and 14b in the eaves-ridge direction in the solar cell panel 14. Notably, in the present embodiment, there is exemplarily presented the case where frames are not attached to end edges of the solar cell panel 14 on both sides in the beam direction (that is, the short side portions thereof).

The frame 16 is preferably fixed to the end edge 14a positioned on the eaves side of the solar cell panel 14 in the state at the time when the solar cell module 12 is installed on the roof 1. By doing this, when the solar cell module 12 is installed, the frame 16 is fixed to the eaves-side end edge 14a which is the lower end edge of the solar cell panel 14 installed on the roof 1 in a downwardly sloping posture, and hence, it can be installed without a risk that the solar cell panel 14 will come out of an inner groove of the frame 16 mentioned later. It should be noted that, not limited to this, the frame 16 may be fixed only to the ridge-side end edge 14b of the solar cell panel 14 in the state where the solar cell module 12 is installed on the roof 1.

The frame 16 has a hollow main body part 18 having a sectionally rectangular solid-shaped external form, and a laterally L-shaped hook part 20 integrally formed with the upper part of the main body part 18. A groove 22 is formed by the main body part 18 and the hook part 20. Hereafter, this groove 22 is referred to as an “inner groove” which means that it faces the inside of the solar cell module 12. The inner groove 22 opens toward one side in the direction perpendicular to the longitudinal direction of the frame 16. It is preferable that the eaves-side end edge 14a of the solar cell panel 14 be inserted into this inner groove 22, and bonded and fixed thereinto, for example, with a silicone-based adhesive agent or the like.

Moreover, the frame 16 has a plate-shaped attachment part 24 at the lower end part of the main body part 18. The attachment part 24 includes an inner attachment part 24a protruding from the main body part 18 toward the solar cell panel 14 side, and an outer attachment part 24b protruding from the main body part 18 toward the opposite side. In the present embodiment, there is presented an example in which the inner attachment part 24a is formed to be longer than the outer attachment part 24b. It should be noted that the protruding lengths of these attachment parts 24a and 24b from the main body part 18 may be the same.

Furthermore, the frame 16 has a lower wall part 26a and an upper wall part 26b, each of which is integrally formed to protrude from the lateral surface, of the main body part 18, which is positioned on the opposite side to the solar cell panel 14. Further, between the lower wall part 26a and the upper wall part 26b, there is formed another groove 28 besides the aforementioned inner groove 22. This other groove 28 is a groove into which a ridge-side end edge 14b of a solar cell panel 14 constituting the solar cell module 12 is inserted, and opens toward the opposite side to the inner groove 22. Moreover, the other groove 28 is formed downward of the aforementioned inner groove 22 by a predetermined dimension. This predetermined dimension corresponds to the step 3 of the step-roofed shape roof 1 as mentioned above. Hereafter, this other groove 28 is referred to as an “outer groove” which means that it faces the outside of the solar cell module 12.

FIG. 4 is a side view showing a solar cell module packaging structure 80A. FIG. 4 shows a structure which enables two solar cell modules 12u and 12d to be stacked and packaged. In this packaging structure 80A, the solar cell module 12u is disposed on the upper side, and the solar cell module 12d is disposed on the lower side.

As shown in FIG. 4, in the packaging structure 80A of the solar cell modules 12, there is achieved the state where the one solar cell module 12d is disposed upside down, and the other solar cell module 12u is stacked thereon. In this state, the ridge-side end edge 14b of the solar cell panel 14 in the one solar cell module 12d is positioned on the inner attachment part 24a of the frame 16 in the other solar cell module 12u, and the didge-side end edge 14b of the solar cell panel 14 in the other solar cell module 12u is positioned below the inner attachment part 24a of the frame 16 in the one solar cell module 2d. In this state, a space 30 is formed between the individual rear surfaces 15b of the solar cell panels 14 of the two solar cell modules 12u and 12d. The terminal boxes 17 and 17 disposed on the individual rear surfaces of the panels of the solar cell modules 12 are contained in this space 30. The size of the space 30 in the upper/lower direction only has to be formed to be slightly larger than the protruding height of the terminal box 17. In this case, the two terminal boxes 17 and 17 do not interfere with each other since they are positioned to be displaced in the horizontal direction.

The two solar cell modules 12u and 12d stacked on each other as above are packaged in the state where the individual terminal boxes 17 of the solar cell modules 12 are contained in the space 30 formed between the solar cell panels 14, and hence, the terminal boxes 17 can be securely packaged without external force exerted thereon. As a result, breakage of the terminal box 17 can be prevented.

Moreover, as shown in FIG. 4, there may be a configuration in which spacer members 32 disposed in the aforementioned space 30 support the ridge-side end edges (the other end edges) 14b of the solar cell panels 14 in the solar cell modules 12u and 12d. The spacer member 32 can be formed of a packaging material such as, for example, styrene foam and corrugated cardboard. With this configuration, it is possible to support the solar cell panel 14 which is supported in the cantilever state by the frame 16 in a more stable state. Notably, the ridge-side end edge 14b of the solar cell panel 14 in the lower solar cell module 12d is held in a stable state by being sandwiched between the spacer member 32 and the inner attachment part 24a of the frame 16.

FIG. 5 is a side view exemplarily showing a solar cell module packaging structure. A packaging structure 80B shown in FIG. 5 and described in the following is different from the aforementioned packaging structure 80A that was described with reference to FIG. 4. Namely, as shown in FIG. 5, in the solar cell module packaging structure 80B, in place of the spacer members, holding parts 19 are provided to protrude on the lateral surfaces of the main body parts 18 of the frames 16, and the ridge-side end edge 14b of the solar cell panel 14 in the solar cell module 12u is supported in the state where it is placed on the holding part 19. The holding part 19 is formed to extend from the lateral surface of the main body part 18 of the frame 16 to face the inner attachment part 24a. It is preferable that the gap between the holding part 19 and the inner attachment part 24a be formed to be slightly larger than the thickness of the ridge-side end edge 14b of the solar cell panel 14. By providing the holding part 19 as above, it is possible to support the ridge-side end edge 14b of the solar cell panel 14, which is in the cantilever state, in a stable state. Moreover, by the holding part 19 integrally provided with the frame 16, a spacer member is not needed and the amount of the packaging material used can be reduced.

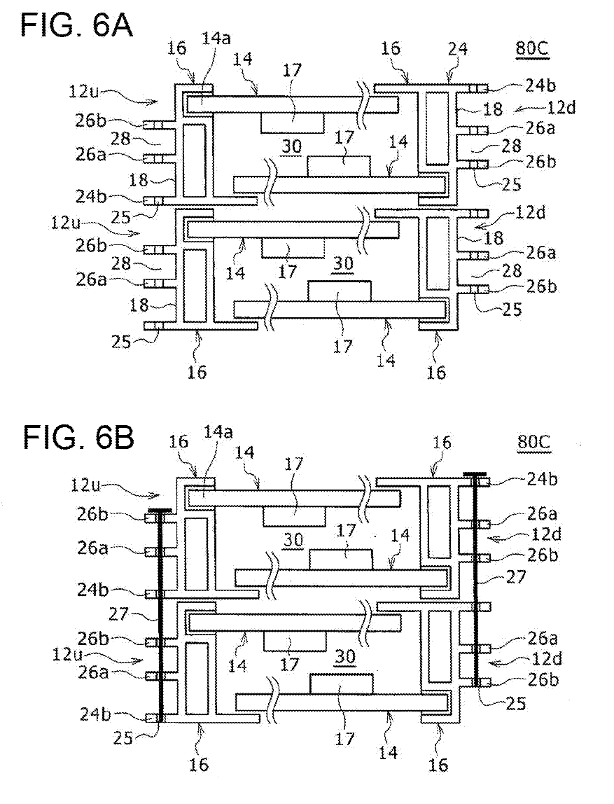

FIGS. 6A and 6B are side views showing a packaging structure 80C in which sets of two solar cell modules are stacked into a plurality of stages. As exemplarily shown in FIG. 6A, the solar cell module packaging structure 80C is configured by stacking sets of the two solar cell modules 12u and 12d stacked on each other as shown in FIG. 4 into two stages. In this case, the frame 16 of each of the solar cell modules 12u and 12d included in the packaging structure 80C has the outer attachment part 24b, the lower wall part 26a and the upper wall part 26b as protruding parts protruding from its lateral surface toward the opposite side to the solar cell panel 14. Through holes 25 are respectively formed in the outer attachment part 24b, the lower wall part 26a and the upper wall part 26b in the state where they are aligned in the upper/lower direction. A fixing through rod (rod member) 27 is inserted into the through holes 25 in the upper/lower direction to penetrate the through holes 25 of the outer attachment parts 24b, and the lower wall parts 26a and the upper wall parts 26b of the frames 16 that are positioned on the same side, out of those of the solar cell modules stacked into the plurality of stages. The fixing through rod 27 is formed, for example, of a metal rod and its upper end part has an expanded diameter, for example, like the head of a nail, so that it engages with the peripheral edge of the upper most through hole 25 to avoid dropping-off.

As above, when the packaging structure 80C is configured by stacking sets of the two solar cell modules 12u and 12d combined into a plurality of stages, compared with a case where the sets are individually packaged, there are advantages that the packaging material can be reduced and that packaging operation can be facilitated. Moreover, by the insertion and penetration of the fixing through rod 27 upward/downward, the cell modules 12 stacked upward/downward can be securely prevented from being displaced in the horizontal direction.

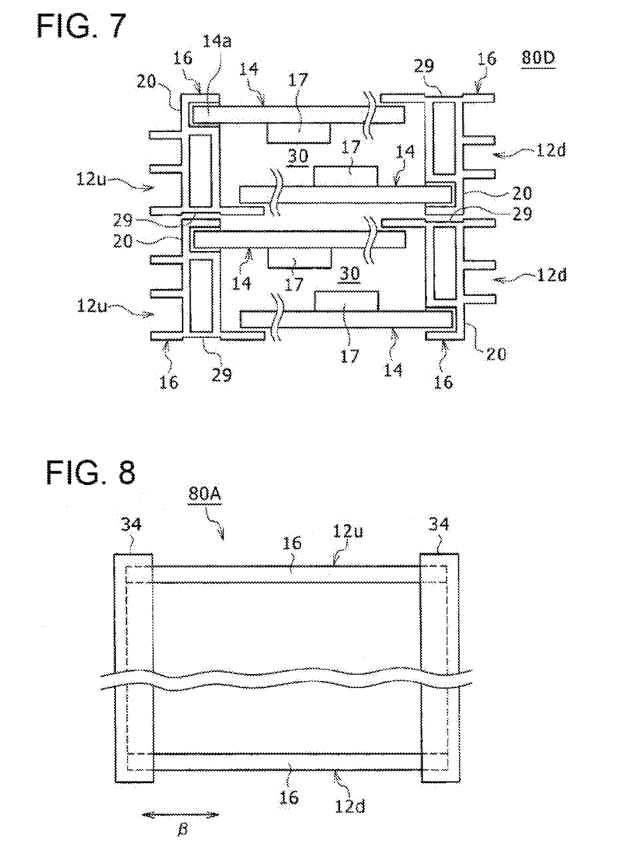

FIG. 7 is a side view still exemplarily showing a packaging structure having sets of the two solar cell modules 12u and 12d stacked into a plurality of stages. As shown in FIG. 7, in this packaging structure 80D, recess parts 29 are formed on the bottom surfaces of the frames 16 of the solar cell modules 12u and 12d (that is, the lower surfaces of the attachment parts 24). Thereby, the upper end parts of the hook parts 20 which are the end parts on the inner groove 22 side in the frames 16 are configured so as to fit into the aforementioned recess parts 29 when the two solar cell modules 12u and 12d are stacked into a plurality of stages. Also in the case of such a configuration, the sets of the solar cell modules 12u and 12d stacked into the plurality of stages can be prevented from being displaced in the horizontal direction.

FIG. 8 is a top view showing an example of providing packaging materials on both end parts of the solar cell modules in the solar cell module packaging structure. As shown in FIG. 8, in the packaging structure 80A configured by stacking at least two solar cell modules 12u and 12d, both end parts of the solar cell modules 12u and 12d in the beam direction β are respectively covered by packaging materials 34 such as, for example, corrugated cardboard. Doing this is effective in the short side end parts, of the solar cell panels 14, to which frames are not attached. Notably, similarly to the packaging structures 80B, 80C and 80D shown in FIG. 5 to FIG. 7, both end parts of the solar cell modules 12u and 12d in the beam direction β may be respectively covered by packaging materials such as, for example, corrugated cardboard.

As mentioned above, according to the solar cell module packaging structures 80A to 80D of the present embodiments, when a plurality of solar cell modules 12 are collectively packaged, they can be securely packaged without external force exerted on the terminal boxes 17 on the rear surfaces of the solar cell panels 14. Moreover, by collectively packaging a plurality of solar cell modules 12 as above, the amount the packaging material used can be reduced, packaging operation can be facilitated, and moreover, they can be efficiently transported.

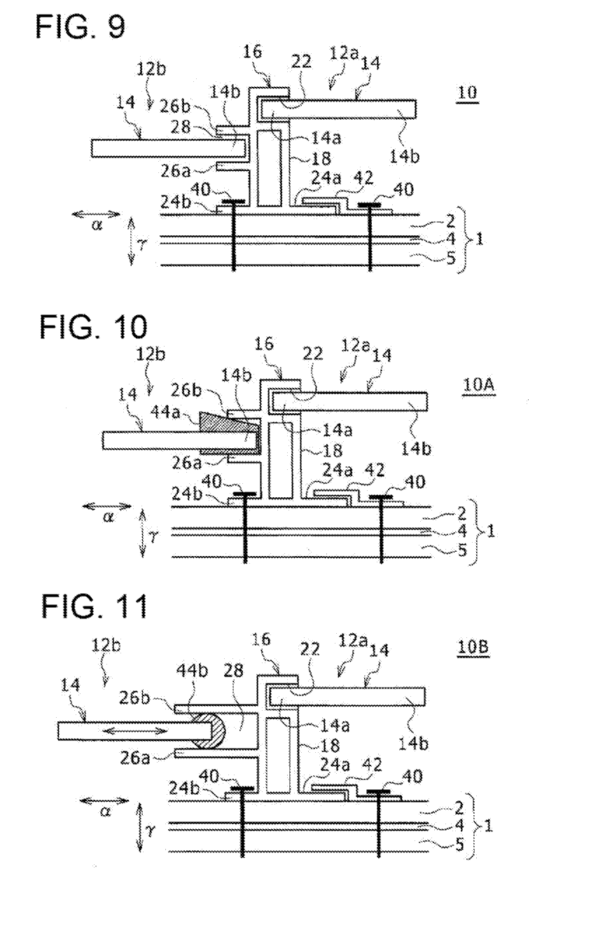

Next, referring to FIGS. 9 to 14, there are described cases of configuring the solar power generation device 10 by installing the solar cell modules 12 in each of which a frame is fixed only to one end edge of a solar cell panel, on the roof 1.

FIG. 9 is a view exemplarily showing a state where the solar cell modules 12 are installed on the roof 1. As mentioned above with reference to FIG. 1, the solar power generation device 10 is configured by installing the plurality of solar cell modules 12, in each of which the frame 16 is fixed only to the eaves-side end edge out of two end edges, in the eaves-ridge direction in the solar cell panel 14 to line up in the eaves-ridge direction.

The solar cell modules 12 are sequentially installed from the ridge side on the roof 1. Herein, as shown in FIG. 9, the roof 1 is constituted of the roof materials 2 such as, for example, slate materials, the waterproof sheet 4 therebelow, and the sheathing roof board 5 therebelow.

As shown in FIG. 9, the frame 16 of the solar cell module 12 is fixed onto the roof 1 by a fixing member 40 such as, for example, a nail or a wood screw driven into the outer attachment part 24b to penetrate to the sheathing roof board 5, and the inner attachment part 24a pressed by a pressing metal fitting 42. The pressing metal fitting 42 is formed by performing folding processing, for example, of a metal plate into a laterally crank shape, and is fixed onto the roof 1 by a fixing member 40 such as, for example, a nail driven to penetrate the sheathing roof board 5. Herein, it is preferable that a plurality of fixing members 40 provided to penetrate the outer attachment part 24b of the frame 16 and a plurality of pressing metal fittings 42 pressing the inner attachment part 24a of the frame 16 be disposed spaced in the longitudinal direction (or extending direction) of the frame 16.

Marks indicating positions where the fixing members 40 are put through, or predrilled holes with a smaller diameter than that of the fixing member 40, may be formed in advance in the outer attachment part 24b of the frame 16. By doing this, the positions where the fixing members 40 are put through become constant, which enables a fixing operation of the solar cell module 12 via the frame 16 to be quickly and stably performed. Moreover, while in the above there is described the example of fixing the inner attachment part 24a of the frame 16 by the pressing metal fitting 42, the inner attachment part 24a may also be fixed by driving the fixing member 40 therein. Moreover, the outer attachment part 24b may be fixed by the pressing metal fitting 42.

Notably, the ridge-side end edge 14b of the solar cell panel 14 in the solar cell module 12 fixed onto the roof 1 as described above can be supported using a frame in a shape in which the lower wall part 26a and the upper wall part 26b are removed from the frame 16. In more detail, the ridge-side end edge 14b of the solar cell panel 14 is inserted into the inner groove 22 of such a frame, and in this state, the attachment parts 24a and 24b of the frame are fixed onto the roof 1 using the fixing member 40, the pressing metal fitting 42 and the like. At this stage, the ridge-side end edge 14b of the solar cell panel 14 may be fixed into the inner groove 22 by applying an adhesive agent in advance on the outer surface of the ridge-side end edge 14b of the solar cell panel 14 or in the inner groove 22.

The procedure of fixing the frame 16 onto the roof 1 is as follows. First, the pressing metal fitting 42 is fixed onto the roof 1 with the fixing member 40. After that, the inner attachment part 24a of the frame 16 of the solar cell module 12a is inserted therein from the eaves side. Then, the frame 16 is fixed by putting the fixing member 40 through the outer attachment part 24b thereof. According to such a procedure, the pressing metal fitting 42 can be installed at a lower position of the solar cell panel 14 of the solar cell module 12a. Moreover, when notch parts are formed in advance in the lower wall part 26a and the upper wall part 26b of the frame 16 corresponding to the fixing members 40, the fixing members 40 can be perpendicularly put through the outer attachment part 24b.

After the solar cell module 12a positioned on the most ridge side of the roof 1 is installed as above, subsequently, another solar cell module 12b is installed adjacent thereto on the eaves side. As to the other solar cell module 12b, first, the ridge-side end edge 14b of the solar cell panel 14 is inserted into the outer groove 28 of the frame 16 of the previously installed solar cell module 12a. At this stage, it is preferable that an adhesive agent be applied in advance on the outer surface of the ridge-side end edge 14b of the solar cell panel 14 or in the outer groove 28, and that the ridge-side end edge 14b of the solar cell panel 14 be fixed into the outer groove 28.

Then, in the state where the ridge-side end edge 14b of the solar cell panel 14 is inserted into the outer groove 28, the position of the frame 16 of the other solar cell module 12b is determined, and the frame 16 is fixed onto the roof 1 using the fixing member 40 such as a nail and the pressing metal fitting 42 similarly to the above.

As above, the solar cell modules 12a and 12b are sequentially installed to the eaves side, and as a result, the solar power generation device 10 constituted of the solar cell modules 12, in each of which the frame 16 is fixed only to the eaves-side end edge 14a of the solar cell panel 14, can be installed on the roof 1.

FIG. 10 is a view exemplarily showing a state where the panel end part 14b of the solar cell module 12 is attached to the frame 16 via a packing member 44a. In this solar power generation device 10A, the packing member 44a is preferably formed of a flexible elastic material such as, for example, rubber. The packing member 44a is provided to cover the ridge-side end edge 14b of the solar cell panel 14. By providing such a packing member 44a, the ridge-side end edge 14b of the solar cell panel 14 can be prevented from rattling in the outer groove 28. Moreover, when the upper surface of the packing member 44a is formed into a tapered surface downwardly sloping toward the ridge side, the upper surface of the packing member 44a can be more securely brought into a state where it is in contact with the upper wall part 26b in insertion into the outer groove 28, and hence, the aforementioned effect of preventing rattling can be further secured.

FIG. 11 is a view exemplarily showing a state where the panel end part 14b of the solar cell module 12b is attached to the frame 16 via a packing member 44b. In this solar power generation device 10B, the protruding lengths of the lower wall part 26a and the upper wall part 26b of the frame 16 are formed to be longer compared with those in FIG. 9, and the packing member 44b which is provided to cover the ridge-side end edge 14b of the solar cell panel 14 and is, for example, sectionally C-shaped, is inserted into the outer groove 28. In this case, the upper and lower portions of the packing member 44b can come into sliding contact with the lower wall part 26a and the upper wall part 26b, and meanwhile, the solar cell panel 14 can be moved along the eaves-ridge direction α. As a result, the solar cell panel 14 can be prevented from rattling, and the installation position of the solar cell module 12b installed on the eaves side can be adjusted.

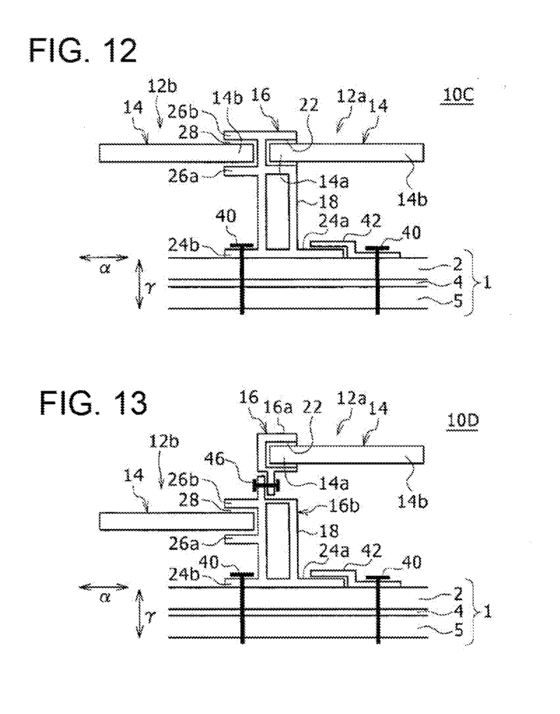

FIG. 12 is a side view exemplarily showing installation in which the solar cell panels of two solar cell modules are flush with each other. In this solar power generation device 10C, the inner groove 22 and the outer groove 28 in the frame 16 are provided at the same height positions. Namely, the lower wall part 26a and the upper wall part 26b which segmentally form the outer groove 28 are formed more upward than those in the frames 16 shown in FIG. 9 to FIG. 11. As a result, the solar cell panels 14 of two solar cell modules 12 adjacent in the eaves-ridge direction α are brought flush with each other. As a result, in the case of installation on a relatively flat roof (for example, a metal plate-roofed roof) other than the step-roofed shape roof, the appearance thereof matches the surface shape of the roof, which results in an improved design.

FIG. 13 is a view exemplarily showing a frame upper part detachably fastened to a frame lower part. In this solar power generation device 10D, in the frame 16, a frame upper part 16a including the inner groove 22 and a frame lower part 16b including the outer groove 28 are separably coupled to each other by a fastening member 46 such as, for example, a bolt and a nut, or a rivet. By configuring the frame 16 as above, for example, in the case where the solar cell panel 14 fixed to the inner groove 22 breaks or a similar case arises, by releasing the fastening with the fastening member 36, it is possible to achieve replacement using another frame upper part 16a to which a new solar cell panel 14 is fixed. Accordingly, this leads to an advantage that solar cell panels 14 can be easily replaced.

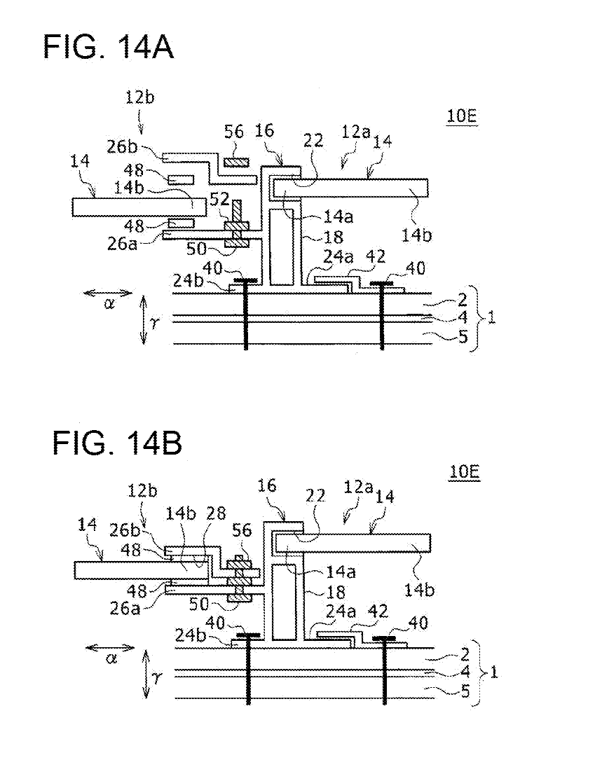

FIGS. 14A and 14B are views exemplarily showing the outer groove 28 provided in the frame 16 being formed by a detachable upper wall part 26b. In this solar power generation device 10E, as shown in FIG. 14A, only the lower wall part 26a is integrally formed to protrude on the frame 16, and the upper wall part 26b is fixed to this lower wall part 26a using a bolt 50, a nut 56 and a spacer 52. By fixing the upper wall part 26b as above, the outer groove 28 is segmentally formed in the frame 16.

The ridge-side end edge 14b of the solar cell panel 14 in the solar cell module 12b installed on the eaves side is fixed so as to be sandwiched between the lower wall part 26a and the upper wall part 26b via packing members 48 composed of elastic materials such as, for example, rubber and sponge. When the upper wall part 26b to form the outer groove 28 is configured to be detachable as above, replacement is facilitated, for example, in the case where the solar cell panel 14 of the solar cell module 12b breaks or a similar case arises after the solar power generation device 10E is installed.

According with each of the aforementioned solar power generation devices 10A to 10E, similarly to the solar power generation device 10 described with reference to FIG. 9, there the solar power generation device 10 constituted by the solar cell modules 12, in each of which the frame 16 is fixed only to the eaves-side end edge 14a out of two edges in the eaves-ridge direction in the solar cell panel 14, can be installed on the roof 1.

Notably, a solar cell power generation device according to the present disclosure is not limited to the aforementioned embodiments and their modifications, and various alterations and improvements thereof are possible.

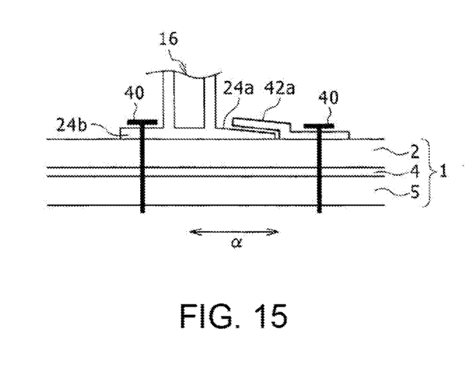

For example, in the above, there has been described the case where the pressing metal fitting 42 for fixing the frame 16 of the solar cell module 12 is formed by folding a metal plate such that it has a crank-like lateral shape, and it presses and fixes the inner attachment part 24a of the frame 16 in the upper/lower direction γ. Nevertheless, as shown in FIG. 15, the pressing metal fitting 42a may be formed to have a pressing portion which comes into contact with the inner attachment part 24a and has an obliquely sloping angle, and as a result of this, the upper surface of the inner attachment part 24a may be formed to have a tapered surface downwardly sloping toward the ridge side. With this configuration, there can be achieved an advantage that even in the case of a processing error at the pressing portion of the pressing metal fitting 42a, the pressing metal fitting 42a can come into tight contact with the upper surface of the inner attachment part 24a to press-fix the same.

Moreover, in the above, there has been described the example in which the end edge 14a of the solar cell panel 14 is directly fixed into the inner groove 22 of the frame 16 with an adhesive agent, the solar cell power generation device is limited to this. An attachment composed of a metal or an elastic body which is thinner than the protruding height of the terminal box 17 may be attached to the end edge 14a of the solar cell panel 14, and the end edge 14a may be fixed into the inner groove 22 of the frame 16 via this attachment.

### REFERENCE SIGNS LIST

1 Roof
2, 2a, 2b Roof material
3 Step
4 Waterproof sheet
5 Sheathing roof board
10, 10A, 10B, 10C, 10D, 10E Solar power generation device
12, 12a, 12b, 12d, 12u Solar cell module
14 Solar cell panel
14a Eaves-side end edge (one end edge)
14b Ridge-side end edge or panel end part (the other end edge)
15a Front surface (of a solar cell panel)
15b Rear surface (of a solar cell panel)
16 Frame
16a Upper part (of a frame)
16b Lower part (of a frame)
17 Terminal box
18 Main body part
19 Holding part
20 Hook part
22 Inner groove (groove)
24 Attachment part
24a Inner attachment part
24b Outer attachment part
25 Through hole
26a Lower wall part
26b Upper wall part
27 Fixing through rod (rod member)
28 Outer groove (another groove)
29 Recess part
30 Space
32 Spacer member
36 Fastening member
40 Fixing member
42, 42a Pressing metal fitting
44a, 44b, 48 Packing member
46 Fastening member
50 Bolt
52 Spacer
56 Nut
80A, 80B, 80C, 80D Packaging structure
α Eaves-ridge direction
β Beam direction
γ Upper/lower direction

1. A solar cell module packaging structure which enables two solar cell modules to be stacked and packaged, the solar cell module including a solar cell panel and a frame having a groove into which an end edge of the solar cell panel is inserted and fixed, wherein
the frame is fixed only to one end edge, of two end edges, in a predetermined direction in the solar cell panel, one of the two solar cell modules is disposed upside down and the other thereof is stacked thereon, in this state, rear surfaces of the solar cell panels included in the respective two solar cell modules face each other, the rear surface being a surface on an opposite side to a surface, of the solar cell panel, which solar light is directly incident on, and a space is formed between the rear surfaces.

2. The solar cell module packaging structure according to claim 1, wherein
a terminal box is provided to protrude on the rear surface, and a size of the space between the rear surfaces in an upper/lower direction is larger than a protruding height of the terminal box from the rear surface of the solar cell panel.

3. The solar cell module packaging structure according to claim 1, wherein
the other end edge of the solar cell panel in the predetermined direction in the solar cell module positioned upward is supported by a spacer member disposed in the space.

4. The solar cell module packaging structure according to claim 1, wherein
a holding part is provided to protrude on a lateral surface of the frame, and the other end edge of the solar cell panel in the predetermined direction in the solar cell module positioned upward is supported in a state of being placed on the holding part.

5. The solar cell module packaging structure according to claim 1, wherein
sets of the two solar cell modules stacked on each other are stacked into a plurality of stages.

6. The solar cell module packaging structure according to claim 5, wherein
the frame has a protruding part protruding to an opposite side to the solar cell panel, a through hole is formed in the protruding part, and a rod member is inserted into the through holes of the protruding parts of the frames positioned on the same side in the solar cell modules that are stacked into the plurality of stages.

7. The solar cell module packaging structure according to claim 5, wherein
a recess part is formed on a bottom surface of the frame, and an end part on the groove side in the frame is fitted into the recess part when the two solar cell modules are stacked into the plurality of stages.

8. The solar cell module packaging structure according to claim 1, wherein
both end parts of the solar cell module in a longitudinal direction of the frame are covered by packaging materials.

9. A solar power generation device configured by installing a plurality of solar cell modules to line up in a eaves-ridge direction on a roof, the solar cell module including a solar cell panel and a frame fixed only to one end edge, of two end edges, in a predetermined direction in the solar cell panel, wherein
the frame has a groove into which the one end edge of the solar cell panel is fixed, and another groove which opens on an opposite side to the groove,
the solar power generation device includes a first solar cell module installed on a ridge side of the roof and a second solar cell module installed to line up on an eaves side with respect to the first solar cell module, and the first and second solar cell modules are installed to cause their frames to face the eaves side, and
the other end edge of the solar cell panel in the predetermined direction in the second solar cell module is inserted into the other groove in the frame of the first solar cell module.

10. The solar power generation device according to claim 9, wherein
the first and second solar cell modules are fixed by at least one of a fixing member sticking into the roof to penetrate an attachment part formed in a lower end part of the frame, and a pressing metal fitting fixed onto the roof so as to press the attachment part.

11. The solar power generation device according to claim 9, wherein
the other end edge of the solar cell panel in the second solar cell module is inserted into the other groove of the frame of the first solar cell module via a packing member.

12. The solar power generation device according to claim 11, wherein
the packing member is provided to be able to adjust a position of the other end edge of the solar cell panel in the other groove in the predetermined direction.

13. The solar power generation device according to claim 9, wherein
the other groove in the frame of the first solar cell panel is formed downward of the groove by a predetermined dimension.

14. The solar power generation device according to claim 9, wherein
the groove and the other groove in the frame of the first solar cell panel are provided at the same height positions.

15. The solar power generation device according to claim 9, wherein
in the frame, a frame upper part including the groove and a frame lower part including the other groove are separably fastened by a fastening member.

16. The solar power generation device according to claim 9, wherein
the other groove is formed between a lower wall part integrally formed with the frame and an upper wall part fixed to the lower wall part by a fastening member, and
the other end edge of the solar cell panel in the predetermined direction in the second solar cell module is fixed so as to be sandwiched between the lower wall part and the upper wall part via a packing member.
